(19) United States
(12) Patent Application Publication
(10) Pub. No.: US 2025/0329554 A1
(43) Pub. Date: Oct. 23, 2025

(54) SUBSTRATE PROCESSING APPARATUS AND SUBSTRATE PROCESSING METHOD

(71) Applicant: Tokyo Electron Limited, Tokyo (JP)

(72) Inventor: Kenji Goto, Koshi-shi, Kumamoto (JP)

(21) Appl. No.: 18/868,430

(22) PCT Filed: May 12, 2023
(86) PCT No.: PCT/JP2023/017840

§ 371 Date: Nov. 22, 2024

(30) Foreign Application Priority Data
May 27, 2022 (JP) 2022-086603

(51) Int. Cl. H01L 21/67; H01L 21/3213

(52) U.S. Cl. CPC H01L 21/67086; H01L 21/32134

(57) ABSTRACT

A substrate processing apparatus includes a processing tub, a discharge opening group, an overflow tub, a circulation path, a liquid feeder, a first gas supply, a second gas supply, a first adjuster, a second adjuster and a controller. In the processing tub, an etching process is performed by immersing a substrate having a metal film in a processing liquid. The discharge opening group serves to discharge the processing liquid to an inside of the processing tub. The liquid feeder sends the processing liquid stored in the overflow tub into the circulation path. The first gas supply discharges a gas to the inside of the processing tub. The second gas supply discharges a gas to an inside of the overflow tub. The controller is configured to perform adjusting a concentration of an intermediate, which contributes to a reaction of the metal film, on a surface of the substrate.

### TECHNICAL FIELD

The various aspects and embodiments described herein pertain generally to a substrate processing apparatus and a substrate processing method.

### BACKGROUND

Conventionally, there is known a technique of etching a metal film formed on a substrate such as a semiconductor wafer (hereinafter, simply referred to as a wafer) (see, for example, Patent Document 1).

### PRIOR ART DOCUMENT

Patent Document 1: Japanese Patent Laid-open Publication No. 2021-180253

### DISCLOSURE OF THE INVENTION

### Problems to be Solved by the Invention

Exemplary embodiments provide a technique capable of improving the controllability of an etching rate of a metal film.

### Means for Solving the Problems

According to an exemplary embodiment, a substrate processing apparatus includes a processing tub, a discharge opening group, an overflow tub, a circulation path, a liquid feeder, a first gas supply, a second gas supply, a first adjuster, a second adjuster and a controller. In the processing tub, an etching process is performed by immersing a substrate having a metal film in a processing liquid. The discharge opening group is disposed below the substrate within the processing tub, and serves to discharge the processing liquid to an inside of the processing tub. The overflow tub stores therein the processing liquid that has overflowed form the processing tub. The circulation path connects the overflow tub to the discharge opening group. The liquid feeder is configured to send the processing liquid stored in the overflow tub into the circulation path. The first gas supply is disposed below the substrate within the processing tub, and is configured to discharge a gas to the inside of the processing tub. The second gas supply is disposed inside the overflow tub, and is configured to discharge a gas to an inside of the overflow tub. The first adjuster is configured to adjust a flow rate of the gas discharged from the first gas supply. The second adjuster is configured to adjust a flow rate of the gas discharged from the second gas supply. The controller is configured to perform a concentration adjusting process of adjusting a concentration of an intermediate, which contributes to a reaction of the metal film, on a surface of the substrate by controlling the liquid feeder, the first adjuster and the second adjuster to adjust at least one of a flow rate of the processing liquid discharged from the discharge opening group, the flow rate of the gas discharged from the first gas supply, or the flow rate of the gas supplied from the second gas supply.

### Effect of the Invention

According to the exemplary embodiment, it is possible to improve the controllability of the etching rate of the metal film.

### BRIEF DESCRIPTION OF THE DRAWINGS

FIG. 1 is a diagram illustrating an example of a substrate processing.

FIG. 2 is a diagram illustrating the example of the substrate processing.

FIG. 3 is a diagram illustrating an example of a reaction in which nitric acid consumed by an oxidation reaction of a molybdenum film is regenerated.

FIG. 4 is a diagram illustrating a configuration of a substrate processing apparatus according to a first exemplary embodiment.

FIG. 5 is a diagram illustrating a configuration of a processing liquid supply according to the first exemplary embodiment.

FIG. 6 is a diagram illustrating a first gas supply and a second gas supply according to the first exemplary embodiment, seen from above.

FIG. 7 is a flowchart illustrating a sequence of processes performed by the substrate processing apparatus according to the exemplary embodiment.

FIG. 8 is an explanatory diagram illustrating a concentration adjusting process according to the exemplary embodiment.

FIG. 9 is an explanatory diagram illustrating a concentration adjusting process according to a first modification example of the exemplary embodiment.

FIG. 10 is an explanatory diagram illustrating a concentration adjusting process according to a second modification example of the exemplary embodiment.

FIG. 11 is an explanatory diagram illustrating a concentration adjusting process according to a third modification example of the exemplary embodiment.

FIG. 12 is an explanatory diagram illustrating a concentration adjusting process according to a fourth modification example of the exemplary embodiment.

FIG. 13 is an explanatory diagram illustrating a concentration adjusting process according to a fifth modification example of the exemplary embodiment.

### DETAILED DESCRIPTION

Hereinafter, embodiments for a substrate processing apparatus and a substrate processing method according to the present disclosure (hereinafter, referred to as “exemplary embodiments”) will be described in detail with reference to the accompanying drawings. Further, it should be noted that the present disclosure is not limited by the exemplary embodiments. Also, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as a θ direction.

### Substrate Processing

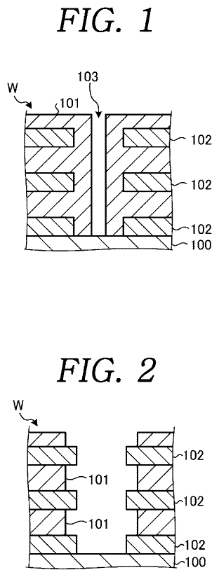

First, an example of a substrate processing according to the present disclosure will be described with reference to FIG. 1 and FIG. 2. FIG. 1 and FIG. 2 are diagrams illustrating an example of the substrate processing.

As shown in FIG. 1, the substrate processing according to the present disclosure is directed to etching a semiconductor wafer (hereinafter, simply referred to as a wafer W) having a molybdenum film (an example of a metal film) 101 and a plurality of silicon oxide films 102 formed on a polysilicon film 100, for example. The plurality of silicon oxide films 102 are formed in multiple layers on the polysilicon film 100 at a certain distance therebetween. The molybdenum film 101 is formed to cover the respective silicon oxide films 102.

As described above, the wafer W according to an exemplary embodiment has a stacked film in which the molybdenum film 101 and the silicon oxide films 102 are alternately stacked, and the silicon oxide films 102 are covered by the molybdenum film 101 before an etching process. Here, the stacked film of the wafer W is not limited to the example shown in FIG. 1 as long as the stacked film includes at least the molybdenum film 101. By way of example, the stacked film may further include a titanium nitride film or a molybdenum nitride film between the molybdenum film 101 and the silicon oxide film 102.

Furthermore, the wafer W is provided with a plurality of grooves 103 through which a processing liquid (etching liquid) is introduced to etch the stacked molybdenum film 101. In FIG. 1, only one groove 103 is illustrated.

In the substrate processing according to the exemplary embodiment, by etching the molybdenum film 101 of the wafer W, a portion (an end portion) of the silicon oxide film 102 is exposed from the molybdenum film 101, as shown in FIG. 2. One containing at least nitric acid (HNO₃), phosphoric acid (H₃PO₄), and water (H₂O) as components thereof is used as the processing liquid for etching the molybdenum film 101. Further, the processing liquid may further contain acetic acid (CH₃COOH).

The etching mechanism of the molybdenum film 101 is as follows. First, as shown in chemical reaction formula (1), the nitric acid (HNO₃) in the processing liquid oxidizes molybdenum to produce molybdic acid (H₂MoO₄) (oxidation reaction of the molybdenum film 101).

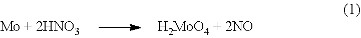

Subsequently, as shown in chemical reaction formula (2), the molybdic acid (H₂MoO₄) reacts with hydroxide ions (OH⁻). As a result, the molybdic acid (H₂MoO₄) is ionized. In other words, the molybdenum film 101 is dissolved (etched).

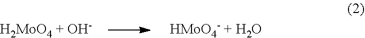

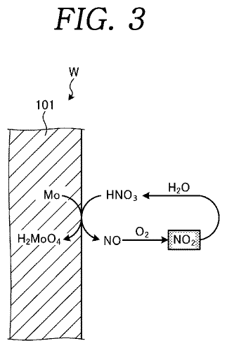

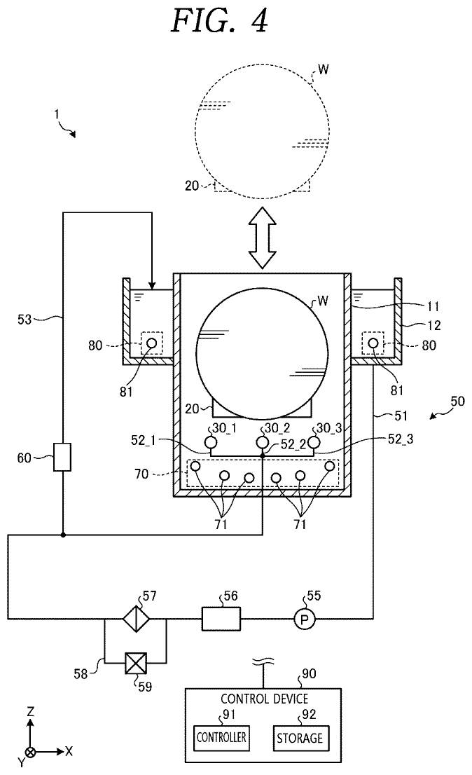

In addition, the nitric acid (HNO₃) consumed by the oxidation reaction of the molybdenum film 101 is regenerated on a surface of the wafer W, as shown in FIG. 3. FIG. 3 is a diagram illustrating an example of a reaction in which the nitric acid (HNO₃) consumed by the oxidation reaction of the molybdenum film 101 is regenerated. That is, as nitrogen monoxide (NO) generated together with the molybdic acid (H₂MoO₄) as a result of the oxidation reaction of the molybdenum film 101 reacts with oxygen (O₂) dissolved in the processing liquid, nitrogen dioxide (NO₂) is generated as an intermediate. Subsequently, the nitrogen dioxide (NO₂) as the intermediate reacts with water (H₂O) in the processing liquid to regenerate the nitric acid (HNO₃) on the surface of the wafer W. The series of reactions for the regeneration of the nitric acid (HNO₃) are expressed by chemical reaction formulas (3) and (4).

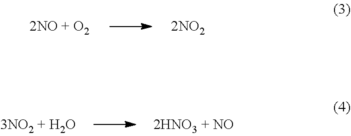

In this way, the etching of the molybdenum film 101 progresses by the oxidation reaction and the dissolution of the molybdenum film 101. Also, the nitric acid (HNO₃) consumed by the oxidation reaction of the molybdenum film 101 is regenerated as the nitrogen dioxide (NO₂) as the intermediate reacts with the water (H₂O) in the processing liquid. Therefore, with an increase of a concentration of the nitrogen dioxide (NO₂) as the intermediate in the processing liquid, the oxidation reaction of the molybdenum film 101 is promoted, so that an etching rate of the molybdenum film 101 increases. On the other hand, with a decrease of the concentration of the nitrogen dioxide (NO₂) as the intermediate, the oxidation reaction of the molybdenum film 101 is suppressed, so that the etching rate of the molybdenum film 101 decreases. From this mechanism, the inventor of the present application has found out that the etching rate of the molybdenum film 101 varies according to a change in the concentration of the nitrogen dioxide (NO₂), which is the intermediate that contributes to the oxidation reaction of the molybdenum film 101, on the surface of the wafer W.

Therefore, in the substrate processing apparatus according to the exemplary embodiment, the etching rate of the molybdenum film 101 is increased or decreased by adjusting the concentration of the nitrogen dioxide (NO₂), which is the intermediate in the processing liquid, on the surface of the wafer W.

In addition, parameters for adjusting the concentration of the nitrogen dioxide (NO₂) as the intermediate on the surface of the wafer W may include a concentration of the oxygen (O₂) dissolved in the processing liquid, a flow velocity of a liquid in a processing tub, and so forth. These parameters can be adjusted by adjusting at least one of a flow rate of the processing liquid and a flow rate of a gas supplied into the processing tub.

Therefore, in the substrate processing apparatus according to the exemplary embodiment, the concentration of the nitrogen dioxide (NO₂) as the intermediate on the surface of the wafer W is adjusted by adjusting at least one of the flow rate of the processing liquid and the flow rate of the gas supplied into the processing tub. This enables improving the controllability of the etching rate of the molybdenum film 101.

### Exemplary Embodiments

### Configuration of Substrate Processing Apparatus

First, a configuration of the substrate processing apparatus according to a first exemplary embodiment will be explained with reference to FIG. 4. FIG. 4 is a diagram illustrating the configuration of the substrate processing apparatus according to the first exemplary embodiment.

A substrate processing apparatus 1 shown in FIG. 4 performs an etching process on a plurality of wafers W all at once by immersing the plurality of wafers W held in a vertical posture in a processing liquid. As described above, the processing liquid containing at least nitric acid, phosphoric acid, and water as components thereof is used for the etching process, and the molybdenum film 101 is etched by this etching process.

As illustrated in FIG. 4, the substrate processing apparatus 1 according to the exemplary embodiment includes an inner tub 11, an outer tub 12, a substrate holder 20, processing liquid supplies 30_1 to 30_3, a circulation path 50, a flow rate adjuster 60, a first gas supply 70, a second gas supply 80, and a control device 90.

In the following description, when the processing liquid supplies 30_1 to 30_3 do not need to be distinguished, they may be simply referred to as a processing liquid supply 30.

### Inner Tub 11 and Outer Tub 12

The inner tub 11 is a box-shaped tank with an open top, and stores the processing liquid therein. A lot formed of a plurality of wafers W is immersed in the inner tub 11. In this way, the inner tub 11 corresponds to an example of a processing tub in which a substrate having a metal film is immersed in the processing liquid to be subjected to an etching process.

The outer tub 12 is disposed around an upper portion of the inner tub 11. The outer tub 12 has an open top and stores therein the processing liquid that has overflowed from the inner tub 11. In this way, the outer tub 12 corresponds to an example of an overflow tub in which the processing liquid that has overflowed from the processing tub is stored.

Further, a new liquid supply configured to replenish the processing liquid may be connected to the outer tub 12. Also, individual supplies configured to individually supply the nitric acid, the phosphoric acid, and the water, which are the components of the processing liquid, may be connected to the outer tub 12.

### Substrate Holder 20

The substrate holder 20 is configured to hold a plurality of wafers W in a vertical posture (a state where they are held vertically). Further, the substrate holder 20 holds the plurality of wafers W at a regular distance therebetween in a horizontal direction (here, in the Y-axis direction). The substrate holder 20 is connected to a non-illustrated elevating mechanism (not shown), and is thus capable of moving the plurality of wafers W between a processing position inside the inner tub 11 and a standby position above the inner tub 11.

### Processing Liquid Supply 30

The processing liquid supply 30 is disposed below the plurality of wafers W inside the inner tub 11, and discharges the processing liquid to the inside of the inner tub 11.

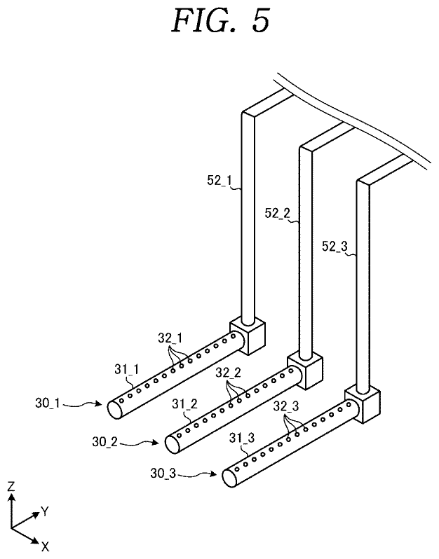

Here, a configuration of the processing liquid supply 30 will be described with reference to FIG. 5. FIG. 5 is a diagram showing the configuration of the processing liquid supply 30 according to the first exemplary embodiment.

As shown in FIG. 5, the processing liquid supplies 30_1 to 30_3 include nozzles 31_1 to 31_3, respectively. Each of the nozzles 31_1 to 31_3 is, for example, a cylindrical member and extends along the arrangement direction (Y-axis direction) of the plurality of wafers W. A multiple number of discharge openings 32_1 to 32_3 are formed in top portions of the nozzles 31_1 to 31_3 along the extension direction of the nozzles 31_1 to 31_3, respectively. The discharge openings 32_1 to 32_3 are of a circular shape, for example, and each has an opening diameter ranging from about 0.5 mm to about 1.0 mm. The processing liquid is discharged from the discharge openings 32_1 to 32_3 vertically upwards (in the positive Z-axis direction).

The nozzles 31_1 to 31_3 are respectively connected to supply paths 52_1 to 52_3 to be described later, and the processing liquid supplied from the supply paths 52_1 to 52_3 is discharged from the multiple number of discharge openings 32_1 to 32_3, respectively.

### Circulation Path 50

Reference is made back to FIG. 4. The circulation path 50 connects the outer tub 12 to the processing liquid supplies 30_1 to 30_3. Specifically, the circulation path 50 includes a discharge path 51, the plurality of supply paths 52_1 to 52_3, and a bypass path 53. The discharge path 51 is connected to a bottom of the outer tub 12.

The discharge path 51 is provided with a pump (an example of a liquid feeder) 55, a heater 56, and a filter 57. The pump 55 is configured to send the processing liquid in the outer tub 12 into the circulation path 50 (discharge path 51). The heater 56 is configured to heat the processing liquid flowing through the discharge path 51 to a temperature suitable for the etching process. The filter 57 is configured to remove impurities from the processing liquid flowing through the discharge path 51. Also, the discharge path 51 is further provided with a filter bypass path 58 that bypasses the filter 57, and the filter bypass path 58 is provided with an opening/closing valve 59 configured to switch an open state/closed state of the filter bypass path 58. The opening/closing valve 59 is electrically connected to and controlled by the control device 90. The opening/closing valve 59 is capable of adjusting the flow rate of the processing liquid flowing through the circulation path 50 (discharge path 51) by switching the open state/closed state of the filter bypass path 58.

The pump 55 and the heater 56 are electrically connected to the control device 90 and are controlled by the control device 90. The pump 55 is capable of adjusting the flow rate of the processing liquid supplied to the processing liquid supply 30 under the control of the control device 90. That is, the pump 55 adjusts the flow rate of the processing liquid supplied from the supply paths 52_1 to 52_3 to the processing liquid supplies 30_1 to 30_3 by changing a liquid feed pressure of the pump 55. In this way, the pump 55 adjusts the flow rate of the processing liquid discharged from the plurality of the discharge openings 32_1 to 32_3 provided in the processing liquid supplies 30_1 to 30_3, respectively.

The plurality of supply paths 52_1 to 52_3 is branched from the discharge path 51. The supply path 52_1 is connected to the processing liquid supply 30_1, the supply path 52_2 is connected to the processing liquid supply 30_2, and the supply path 52_3 is connected to the processing liquid supply 30_3.

The bypass path 53 is branched from the discharge path 51 and connected to the outer tub 12.

### Flow Rate Adjuster 60

The flow rate adjuster 60 is, for example, a liquid flow controller (LFC), and is configured to adjust the flow rate of the processing liquid supplied to the processing liquid supplies 30_1 to 30_3. That is, the flow rate adjuster 60 adjusts the flow rate of the processing liquid discharged from the multiple number of discharge openings 32_1 to 32_3 of the processing liquid supplies 30_1 to 30_3.

Specifically, the flow rate adjuster 60 is provided in the bypass path 53, and serves to adjust the flow rate of the processing liquid flowing through bypass path 53 to adjust the flow rate of the processing liquid supplied from the supply paths 52_1 to 52_3 to the processing liquid supplies 30_1 to 30_3.

The flow rate adjuster 60 is electrically connected to the control device 90 and is controlled by the control device 90.

### First Gas Supply 70 and Second Gas Supply 80

The first gas supply 70 is disposed below the plurality of wafers W and the plurality of processing liquid supplies 30_1 to 30_3 within the inner tub 11. This first gas supply 70 is provided with a plurality of nozzles 71, and discharges a gas from these nozzles 71 to the inside of the inner tub 11. Thus, the first gas supply 70 is capable of adjusting a flow velocity of the processing liquid in the inner tub 11 and a concentration of the oxygen dissolved in the processing liquid.

The second gas supply 80 is disposed inside the outer tub 12. This second gas supply 80 is provided with a plurality of nozzles 81, and discharges a gas from these nozzles 81 to the inside of the outer tub 12. Thus, the second gas supply 80 is capable of adjusting the concentration of the oxygen dissolved in the processing liquid.

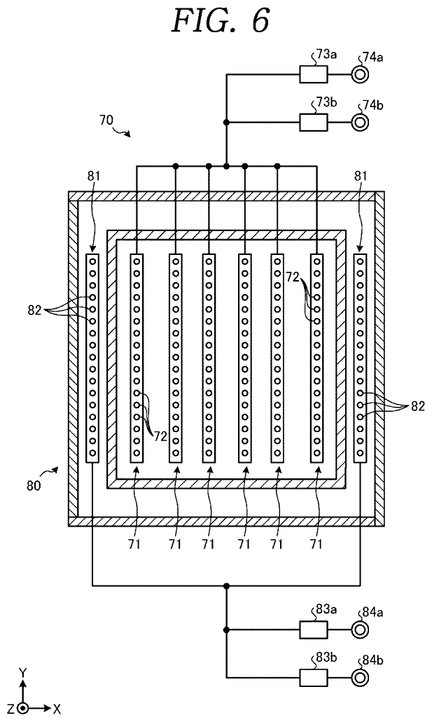

Here, configurations of the first gas supply 70 and the second gas supply 80 will be described with reference to FIG. 6. FIG. 6 is a diagram of the first gas supply 70 and the second gas supply 80 according to the first exemplary embodiment, seen from above.

As illustrated in FIG. 6, each of the plurality of nozzles 71 belonging to the first gas supply 70 is, for example, a cylindrical member and extends in the arrangement direction (Y-axis direction) of the plurality of wafers W. A multiple number of discharge openings 72 is provided in a top portion of each nozzle 71 in the extension direction of the nozzle 71. Here, the multiple number of discharge openings 72 do not necessarily need to be provided in the top portion of the nozzle 71. By way of example, the discharge openings 72 may be provided in a bottom portion of the nozzle 71 to discharge the gas obliquely downwards.

The plurality of nozzles 71 are connected to a gas source 74a via a flow rate adjuster 73a. The gas source 74a supplies a gas to the multiplicity of nozzles 71. In the present exemplary embodiment, it is assumed that a nitrogen (N₂) gas is supplied from the gas source 74a to the plurality of nozzles 71. However, the gas supplied from the gas source 74a to the plurality of nozzles 71 may be, by way of non-limiting example, an inert gas other than nitrogen gas, such as a rare gas. As the rare gas, an argon (Ar) gas or a neon (Ne) gas may be used.

The flow rate adjuster 73a is composed of, for example, an LFC, an opening/closing valve, and so forth, and serves to adjust a flow rate of the nitrogen gas supplied from the gas source 74a to the multiplicity of nozzles 71.

Further, the plurality of nozzles 71 are also connected to a gas source 74b via a flow rate adjuster 73b. The gas source 74b supplies a gas to the plurality of nozzles 71. Here, it is assumed that an oxygen (O₂) gas is supplied from the gas source 74b to the plurality of nozzles 71. However, the gas supplied from the gas source 74b to the plurality of nozzles 71 may be, by way of non-limiting example, an oxygen-containing gas other than the oxygen gas, such as air or an ozone (O₃) gas.

The flow rate adjuster 73b is composed of, for example, an LFC, an opening/closing valve, and so forth, and serves to adjust a flow rate of the oxygen gas supplied the gas source 74b to the multiplicity of nozzles 71.

As stated above, the first gas supply 70 is capable of selectively discharging the nitrogen gas as the inert gas or the oxygen gas as the oxygen-containing gas. The flow rate controllers 73a and 73b are capable of adjusting the flow rates of the nitrogen gas and the oxygen gas discharged from the first gas supply 70, respectively. The flow rate controllers 73a and 73b correspond to an example of a first adjuster configured to adjust the flow rate of the gas discharged from the first gas supply 70.

Furthermore, each of the plurality of nozzles 81 belonging to the second gas supply 80 is, for example, a cylindrical member and extends in the arrangement direction (Y-axis direction) of the plurality of wafers W. A multiple number of discharge openings 82 is provided in a top portion of each nozzle 81 in the extension direction of the nozzle 81. Here, the multiple number of discharge openings 82 do not necessarily need to be provided in the top portion of the nozzle 81. By way of example, the discharge openings 82 may be provided in a bottom portion of the nozzle 81 to discharge a gas obliquely downwards.

The plurality of nozzles 81 are connected to a gas source 84a via a flow rate adjuster 83a. The gas source 84a supplies a gas to the plurality of nozzles 81. Here, although it is assumed that a nitrogen gas is supplied from the gas source 84a to the plurality of nozzles 81, the gas supplied from the gas source 84a to the multiple nozzles 81 may be, by way of non-limiting example, an inert gas other than the nitrogen gas, such as a rare gas. As the rare gas, an argon gas or a neon gas may be used, for example.

The flow rate adjuster 83a is composed of, for example, an LFC, an opening/closing valve, and so forth, and serves to adjust a flow rate of the nitrogen gas supplied from the gas source 84a to the plurality of nozzles 81.

Furthermore, the plurality of nozzles 81 are also connected to a gas source 84b through a flow rate adjuster 83b. The gas source 84b supplies a gas to the plurality of nozzles 81. Here, although it is assumed that an oxygen gas is supplied from the gas source 84b to the multiple nozzles 81, the gas supplied from the gas source 84b to the plurality of nozzles 81 may be, by way of non-limiting example, an oxygen-containing gas other than the oxygen gas, such as air or an ozone gas.

The flow rate adjuster 83b is composed of, for example, an LFC, an opening/closing valve, and so forth, and serves to adjust a flow rate of the oxygen gas supplied the gas source 84b to the plurality of nozzles 81.

In this way, the second gas supply 80 is capable of selectively discharging the nitrogen gas as the inert gas or the oxygen gas as the oxygen-containing gas. The flow rate controllers 83a and 83b are capable of adjusting the flow rates of the nitrogen gas and the oxygen gas discharged from the second gas supply 80, respectively. The flow rate controllers 83a and 83b correspond to an example of a second adjuster configured to adjust the flow rate of the gas discharged from the second gas supply 80.

### Control Device 90

Reference is made back to FIG. 4. The control device 90 is, by way of example, a computer, and includes a controller 91 and a storage 92. The storage 92 is, for example, a semiconductor memory device such as a RAM or a flash memory, or a storage device such as a hard disk or an optical disk, and stores a program that controls various processes implemented in the substrate processing apparatus 1. The controller 91 includes various types of circuits and a microcomputer having a central processing unit (CPU), a read only memory (ROM), a random access memory (RAM), an input/output port, and so forth, and controls the operation of the substrate processing apparatus 1 by reading and executing the program stored in the storage 92.

In addition, the program may be recorded on a computer-readable recording medium and installed from the recording medium into the storage 92 of the control device 90. The computer-readable recording medium may be, by way of example, but not limitation, a hard disk (HD), a flexible disk (FD), a compact disk (CDs), a magnet optical disk (MO), a memory card, or the like.

### Specific Operation of Substrate Processing Apparatus 1

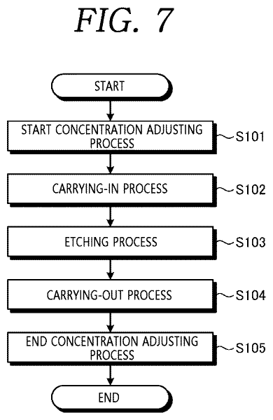

Now, a specific operation of the substrate processing apparatus 1 according to the exemplary embodiment will be described with reference to FIG. 7. FIG. 7 is a flowchart illustrating a sequence of processes performed by the substrate processing apparatus 1 according to the exemplary embodiment. The individual processes shown in FIG. 7 are performed under the control of the controller 91.

As shown in FIG. 7, in the substrate processing apparatus 1, a concentration adjusting process is first started to adjust the concentration of the nitrogen dioxide (NO₂) on the surface of the wafer W in the processing liquid stored in the inner tub 11 (process S101). Here, the nitrogen dioxide (NO₂) is the intermediate that contributes to the oxidation reaction of the molybdenum film 101. This concentration adjusting process will be elaborated later.

Subsequently, in the substrate processing apparatus 1, a carrying-in process of immersing the plurality of wafers W in the inner tub 11 is performed (process S102). In the carrying-in process, the controller 91 controls the non-illustrated elevating mechanism belonging to the substrate holder 20 to lower the substrate holder 20, thus allowing the plurality of wafers W to be immersed in the processing liquid stored in the inner tub 11.

Furthermore, the controller 91 controls the pump 55 to start the supply of the processing liquid from the outer tub 12 to the processing liquid supplies 30_1 to 30_3 prior to starting the carrying-in process. Also, before starting the carrying-in process, the controller 91 controls the flow rate adjuster 60 to close the bypass path 53. In addition, before starting the carrying-in process, the controller 91 controls the opening/closing valve 59 to close the filter bypass path 58. That is, before starting the carrying-in process, all the processing liquid flowing in the circulation path 50 is supplied to the processing liquid supplies 30_1 to 30_3.

Thereafter, in the substrate processing apparatus 1, an etching process is performed (process S103). In the etching process, the state in which the plurality of wafers W are immersed in the processing liquid in the inner tub 11 is maintained for a predetermined time. As a result, the molybdenum film 101 is etched.

Thereafter, in the substrate processing apparatus 1, a carrying-out process is performed (process S104). In the carrying-out process, the controller 91 controls the non-illustrated elevating mechanism of the substrate holder 20 to raise the substrate holder 20, thus allowing the plurality of wafers W to be lifted from the inner tub 11.

Then, the substrate processing apparatus 1 ends the concentration adjusting process (process S105), and ends the series of processes of the substrate processing in the substrate processing apparatus 1.

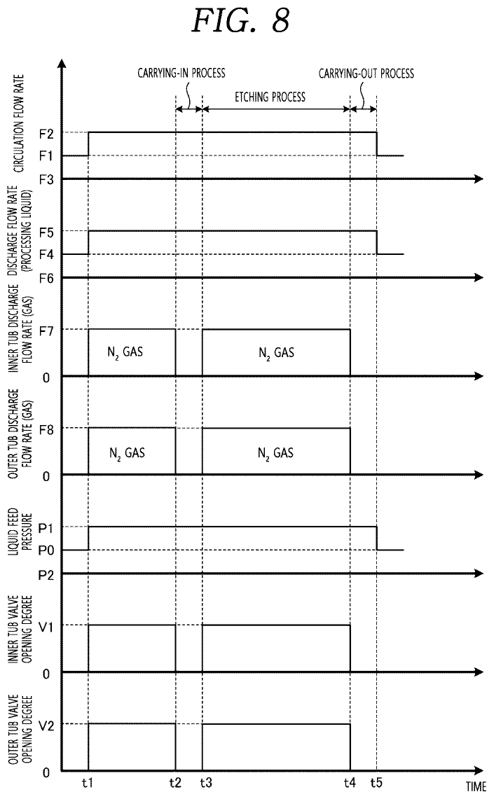

Now, details of the concentration adjusting process will be described with reference to FIG. 8. FIG. 8 is an explanatory diagram illustrating the concentration adjusting process according to the exemplary embodiment.

FIG. 8 shows variations of “circulation flow rate”, “discharge flow rate (processing liquid)”, “inner tub discharge flow rate (gas)”, “outer tub discharge flow rate (gas)”, “liquid feed pressure”, “inner tub valve opening degree” and “outer tub valve opening degree” in the substrate processing performed by the substrate processing apparatus 1 with a lapse of time. The “circulation flow rate” is a flow rate of the processing liquid flowing through the circulation path 50, and the “discharge flow rate (processing liquid)” is a flow rate of the processing liquid discharged from the processing liquid supplies 30_1 to 30_3. Further, the “inner tub discharge flow rate (gas)” is a flow rate of the gas discharged from the first gas supply 70 into the inner tub 11, and the “outer tub discharge flow rate (gas)” is a flow rate of the gas discharged from the second gas supply 80 into the outer tub 12. Also, the “liquid feed pressure” is a liquid feed pressure of the pump 55, that is, a pressure at which the pump 55 sends the processing liquid into the circulation path 50. Furthermore, the “inner tub valve opening degree” is an opening degree of the opening/closing valve (electronic valve) of the flow rate adjuster 73a or the flow rate adjuster 73b, and the “outer tub valve opening degree” is an opening degree of the opening/closing valve (electronic valve) of the flow rate adjuster 83a or the flow rate adjuster 83b.

In addition, in FIG. 8, it is assumed that the first gas supply 70 and the second gas supply 80 discharge a nitrogen (N₂) gas, which is an inert gas.

The controller 91 adjusts the liquid feed pressure of the pump 55, the inner tub valve opening degree of the flow rate adjuster 73a, and the outer tub valve opening degree of the flow rate adjuster 83a to adjust the discharge flow rate of the processing liquid supply 30, the inner tub discharge flow rate of the first gas supply 70, and the outer tub discharge flow rate of the second gas supply 80, respectively. In this way, the controller 91 adjusts the concentration of the nitrogen dioxide (NO₂), which contributes to the reaction of the molybdenum film 101, on the surface of the wafer W.

For instance, in the example shown in FIG. 8, the controller 91 reduces the concentration of the nitrogen dioxide on the surface of the wafer W. That is, the controller 91 increases the liquid feed pressure of the pump 55 from pressure P0 to pressure P1(>P0) at time t1 before time t2 when the carrying-in process is started, thus increasing the discharge flow rate of the processing liquid supplies 30_1 to 30_3 from flow rate F4 to flow rate F5(>F4). The pressure P0 and the flow rate F4 may be, by way of example, a liquid feed pressure of the pump 55 and a discharge flow rate of the processing liquid supplies 30_1 to 30_3 used in the previous substrate processing. Furthermore, the controller 91 may further increase the discharge flow rate of the processing liquid supplies 30_1 to 30_3 by controlling the opening/closing valve 59 to switch the filter bypass path 58 from a closed state to an open state. By increasing the discharge flow rate of the processing liquid supplies 30_1 to 30_3, the controller 91 is capable of increasing the flow velocity of the processing liquid in the inner tub 11.

Further, the controller 91 increases the inner tub valve opening degree of the flow rate adjuster 73a from 0 to opening degree V1 at the time t1, thus increasing the inner tub discharge flow rate of the first gas supply 70 from 0 to flow rate F7. By increasing the inner tub discharge flow rate of the first gas supply 70 to cause bubbling of the nitrogen gas in the inner tub 11, the controller 91 is capable of reducing the concentration of the oxygen (O₂) dissolved in the processing liquid in the inner tub 11.

In addition, by increasing the outer tub valve opening degree of the flow rate adjuster 83a from 0 to opening degree V2 at the time t1, the controller 91 increases the outer tub discharge flow rate of the second gas supply 80 from 0 to flow rate F8. By increasing the outer tub discharge flow rate of the second gas supply 80 to cause bubbling of the nitrogen gas in the outer tub 12, the controller 91 is capable of reducing the concentration of the oxygen (O₂) dissolved in the processing liquid in the inner tub 11.

In this way, in the substrate processing apparatus 1, by increasing the flow velocity of the processing liquid in the inner tub 11, the nitrogen dioxide present on the surface of the wafer W is diffused. Further, in the substrate processing apparatus 1, by reducing the concentration of the oxygen (O₂) dissolved in the processing liquid in the inner tub 11, generation of the nitrogen dioxide is suppressed (see the chemical reaction formula (3)). Accordingly, the controller 91 is capable of reducing the concentration of the nitrogen dioxide on the surface of the wafer W, which is the intermediate that contributes to the oxidation reaction of the molybdenum film 101, before starting the etching process. As a result, since the oxidation reaction of the molybdenum film 101 is suppressed, the etching rate of the molybdenum film 101 can be lowered. That is, according to the substrate processing apparatus 1 of the exemplary embodiment, the controllability of the etching rate of the molybdenum film 101 can be improved.

Subsequently, the controller 91 performs the carrying-in process in a period ranging from the time t2 to time t3. In the carrying-in process, the controller 91 controls the non-illustrated elevating mechanism of the substrate holder 20 to lower the substrate holder 20, thus allowing the plurality of wafers W to be immersed in the processing liquid stored in the inner tub 11. The controller 91 lowers the inner tub valve opening degree of the flow rate adjuster 73a to 0 from the opening degree V1 in the period from the time t2 to the time t3, thereby reducing the inner tub discharge flow rate of the first gas supply 70 from the flow rate F7 to 0. Furthermore, the controller 91 lowers the outer tub valve opening degree of the flow rate adjuster 83a to 0 from the opening degree V2 in the period from the time t2 to the time t3, thus reducing the outer tub discharge flow rate of the second gas supply 80 from the flow rate F8 to 0.

In this way, in the substrate processing apparatus 1, in the period during which the plurality of wafers W are immersed in the processing liquid (that is, the period from the time t2 to the time t3), the discharge of the nitrogen gas from the first gas supply 70 and the second gas supply 80 is stopped. This makes it possible to temporarily reduce the flow velocity of the processing liquid in the inner tub 11, and, as a result, the wafer W can be suppressed from falling off the substrate holder 20.

Subsequently, the controller 91 increases the inner tub valve opening degree of the flow rate adjuster 73a back to the opening degree V1 from 0 at the time t3 when the etching process is started, thus increasing the inner tub discharge flow rate of the first gas supply 70 back to the flow rate F7 from 0. Further, the controller 91 increases the outer tub valve opening degree of the flow rate adjuster 83a back to the opening degree V2 from 0 at the time t3, thus increasing the outer tub discharge flow rate of the second gas supply 80 back to the flow rate F8 from 0. As a result, the controller 91 is capable of reducing the concentration of the nitrogen dioxide, which is the intermediate that contributes to the oxidation reaction of the molybdenum film 101, on the surface of the wafer W during the etching process. This suppresses the oxidation reaction of the molybdenum film 101, so that the etching rate of the molybdenum film 101 can be reduced. That is, according to the substrate processing apparatus 1 of the exemplary embodiment, the controllability of the etching rate of the molybdenum film 101 can be improved.

Subsequently, the controller 91 performs the etching process in a period ranging from the time t3 to time t4.

Then, the controller 91 performs the carrying-out process in a period ranging from the time t4 to time t5. In the carrying-out process, the controller 91 controls the non-illustrated elevating mechanism of the substrate holder 20 to raise the substrate holder 20, thus allowing the plurality of wafers W to be lifted from the processing liquid in the inner tub 11. The controller 91 lowers the inner tub valve opening degree of the flow rate adjuster 73a from the opening degree V1 to 0 in the period from the time t4 to the time t5, thereby lowering the inner tub discharge flow rate of the first gas supply 70 from the flow rate F7 to 0. The controller 91 lowers the outer tub valve opening degree of the flow rate adjuster 83a from the opening degree V2 to 0 in the period from the time t2 to the time t3, thereby lowering the outer tub discharge flow rate of the second gas supply 80 from the flow rate F8 to 0.

In this way, in the substrate processing apparatus 1, in the period during which the plurality of wafers W are lifted from the processing liquid (that is, the period from the time t4 to the time t5), the discharge of the nitrogen gas from the first gas supply 70 and the second gas supply 80 is stopped. This makes it possible to temporarily reduce the flow velocity of the liquid flow of the processing liquid in the inner tub 11, so that the wafer W can be suppressed from falling off the substrate holder 20.

Subsequently, upon the completion of the carrying-out process at the time t5, the controller 91 lowers the liquid feed pressure of the pump 55 from the pressure P1 to the pressure P0(<P1), thus reducing the discharge flow rate of the processing liquid supplies 30_1 to 30_3 from the flow rate F5 to the flow rate F4(<F5). Furthermore, the controller 91 may control the opening/closing valve 59 to switch the filter bypass path 58 from the open state to the closed state, thereby further reducing the discharge flow rate of the processing liquid supplies 30_1 to 30_3. By lowering the discharge flow rate of the processing liquid supplies 30_1 to 30_3, the controller 91 is capable of returning the flow velocity of the processing liquid in the inner tub 11 back to an initial flow velocity.

In the example shown in FIG. 8, the controller 91 adjusts the concentration of the nitrogen dioxide on the surface of the wafer W contributing to the reaction of the molybdenum film 101 by adjusting the discharge flow rate of the processing liquid supply 30, the inner tub discharge flow rate of the first gas supply 70, and the outer tub discharge flow rate of the second gas supply 80. However, the present disclosure is not limited thereto, and the controller 91 may adjust the concentration of the nitrogen dioxide on the surface of the wafer W by adjusting at least one of the discharge flow rate of the processing liquid supply 30, the inner tub discharge flow rate of the first gas supply 70, and the outer tub discharge flow rate of the second gas supply 80. In this case, the controller 91 may reduce the concentration of the nitrogen dioxide on the surface of the wafer W by performing at least one of a process of increasing the discharge flow rate of the processing liquid supply 30, a process of increasing the inner tub discharge flow rate of the first gas supply 70, and a process of increasing the outer tub discharge flow rate of the second gas supply 80.

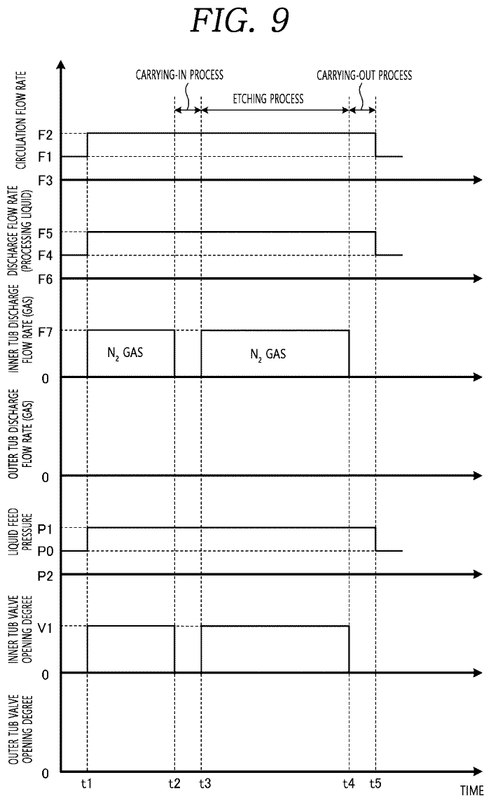

Now, modification examples of the concentration adjusting process shown in FIG. 8 will be described with reference to FIG. 9 to FIG. 13. FIG. 9 is an explanatory diagram illustrating a concentration adjusting process according to a first modification example of the exemplary embodiment.

The concentration adjusting process according to the first modification example is different from the concentration adjusting process shown in FIG. 8 in that it does not cause the bubbling of the nitrogen gas in the outer tub 12 by maintaining the outer tub valve opening degree of the flow rate adjuster 83a at 0 and thus maintaining the outer tub discharge flow rate of the second gas supply 80 at 0. That is, the controller 91 increases only the inner tub discharge flow rate of the first gas supply 70 to cause only the bubbling of the nitrogen gas in the inner tub 11. Accordingly, as compared to the concentration adjusting process shown in FIG. 8, a decrement in the concentration of the oxygen (O₂) dissolved in the processing liquid in the inner tub 11 can be reduced, so that a decrement in the concentration of the nitrogen dioxide on the surface of the wafer W can be reduced. Therefore, according to the first modification example, a decrement in the etching rate of the molybdenum film 101 can be reduced as compared to that in the exemplary embodiment described above.

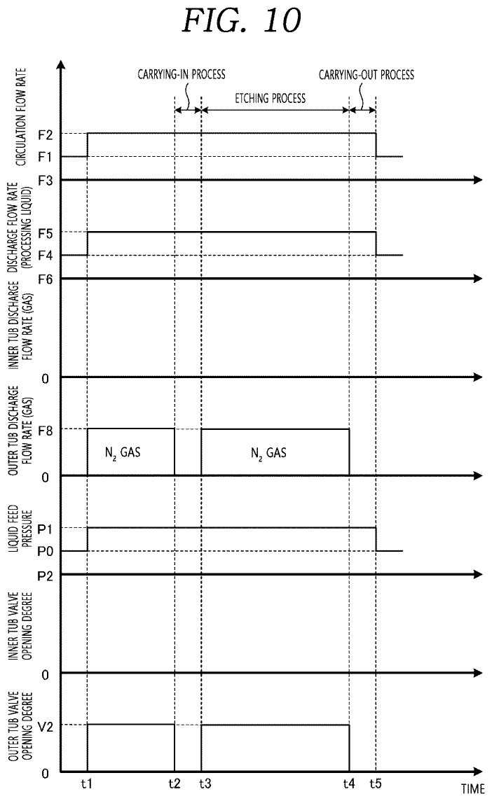

FIG. 10 is an explanatory diagram illustrating a concentration adjusting process according to a second modification example of the exemplary embodiment.

The concentration adjusting process according to the second modification example is different from the concentration adjusting process shown in FIG. 8 in that it does not cause the bubbling of the nitrogen gas in the inner tub 11 by maintaining the inner tub valve opening degree of the flow rate adjuster 73a at 0 and thus maintaining the inner tub discharge flow rate of the first gas supply 70 at 0. That is, the controller 91 increases only the outer tub discharge flow rate of the second gas supply 80 to cause only the bubbling of the nitrogen gas in the outer tub 12. Accordingly, as compared to the concentration adjusting process shown in FIG. 8, the flow velocity of the processing liquid can be lowered while reducing a decrement in the concentration of the oxygen (O₂) dissolved in the processing liquid in the inner tub 11, so that a decrement in the concentration of the nitrogen dioxide on the surface of the wafer W can be reduced. Therefore, according to the second modification example, a decrement in the etching rate of the molybdenum film 101 can be reduced as compared to that in the exemplary embodiment described above.

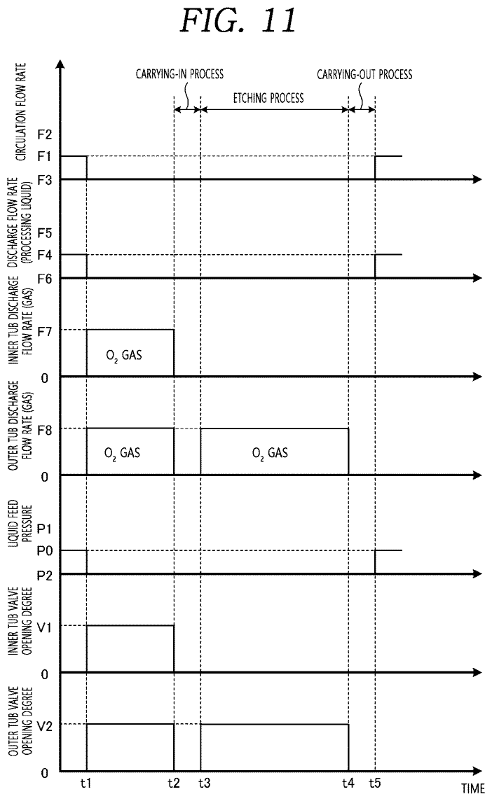

FIG. 11 is an explanatory diagram illustrating a concentration adjusting process according to a third modification example of the exemplary embodiment. In FIG. 11, it is assumed that the first gas supply 70 and the second gas supply 80 discharge an oxygen (O₂) gas, which is the oxygen-containing gas.

The controller 91 adjusts the liquid feed pressure of the pump 55, the inner tub valve opening degree of the flow rate adjuster 73b, and the outer tub valve opening degree of the flow rate adjuster 83b to adjust the discharge flow rate of the processing liquid supply 30, the inner tub discharge flow rate of the first gas supply 70, and the outer tub discharge flow rate of the second gas supply 80. In this way, the controller 91 adjusts the concentration of the nitrogen dioxide on the surface of the wafer W that contributes to the reaction of the molybdenum film 101.

For example, in the example shown in FIG. 11, the controller 91 increases the concentration of the nitrogen dioxide on the surface of the wafer W. That is, the controller 91 reduces the liquid feed pressure of the pump 55 from pressure P0 to pressure P2(<P0) at time t1 before time t2 when the carrying-in process is started, thus reducing the discharge flow rate of the processing liquid supplies 30_1 to 30_3 from flow rate F4 to flow rate F6(<F4). The pressure P0 and the flow rate F4 may be, by way of example, a liquid feed pressure of the pump 55 and a discharge flow rate of the processing liquid supplies 30_1 to 30_3 used in the previous substrate processing. Furthermore, the controller 91 may further reduce the discharge flow rate of the processing liquid supplies 30_1 to 30_3 by controlling the flow rate adjuster 60 to increase the flow rate of the processing liquid flowing in the bypass path 53. By reducing the discharge flow rate of the processing liquid supplies 30_1 to 30_3, the controller 91 is capable of reducing the flow velocity of the processing liquid in the inner tub 11.

Further, the controller 91 increases the inner tub valve opening degree of the flow rate adjuster 73b from 0 to opening degree V1 at the time t1, thus increasing the inner tub discharge flow rate of the first gas supply 70 from 0 to flow rate F7. By increasing the inner tub discharge flow rate of the first gas supply 70 and thus causing bubbling of the oxygen gas in the inner tub 11, the controller 91 is capable of increasing the concentration of the oxygen (O₂) dissolved in the processing liquid in the inner tub 11.

In addition, by increasing the outer tub valve opening degree of the flow rate adjuster 83b from 0 to opening degree V2 at the time t1, the controller 91 increases the outer tub discharge flow rate of the second gas supply 80 from 0 to flow rate F8. By increasing the outer tub discharge flow rate of the second gas supply 80 and thus causing bubbling of the oxygen gas in the outer tub 12, the controller 91 is capable of increasing the concentration of the oxygen (O₂) dissolved in the processing liquid in the inner tub 11.

In this way, in the substrate processing apparatus 1 according to the third modification example, by reducing the flow velocity of the processing liquid in the inner tub 11, the nitrogen dioxide is made to stay on the surface of the wafer W. Further, in the substrate processing apparatus 1, by increasing the concentration of the oxygen (O₂) dissolved in the processing liquid in the inner tub 11, generation of the nitrogen dioxide is promoted (see the chemical reaction formula (3)). Accordingly, the controller 91 is capable of increasing the concentration of the nitrogen dioxide on the surface of the wafer W, which is the intermediate that contributes to the oxidation reaction of the molybdenum film 101, before starting the etching process. As a result, since the oxidation reaction of the molybdenum film 101 is promoted, the etching rate of the molybdenum film 101 can be increased. That is, according to the substrate processing apparatus 1 of the third modification example, the controllability of the etching rate of the molybdenum film 101 can be improved.

Subsequently, the controller 91 performs the carrying-in process in the period ranging from the time t2 to time t3. In the carrying-in process, the controller 91 controls the non-illustrated elevating mechanism of the substrate holder 20 to lower the substrate holder 20, thus allowing the plurality of wafers W to be immersed in the processing liquid stored in the inner tub 11. The controller 91 lowers the inner tub valve opening degree of the flow rate adjuster 73b to 0 from the opening degree V1 during the period from the time t2 onwards, thereby reducing the inner tub discharge flow rate of the first gas supply 70 from the flow rate F7 to 0. Furthermore, the controller 91 lowers the outer tub valve opening degree of the flow rate adjuster 83b to 0 from the opening degree V2 in the period from the time t2 to the time t3, thus reducing the outer tub discharge flow rate of the second gas supply 80 from the flow rate F8 to 0.

In this way, in the substrate processing apparatus 1, in the period during which the plurality of wafers W are immersed in the processing liquid (that is, the period from the time t2 to the time t3), the discharge of the oxygen gas from the first gas supply 70 and the second gas supply 80 is stopped. This makes it possible to reduce the flow velocity of the processing liquid in the inner tub 11, and, as a result, the wafer W can be suppressed from falling off the substrate holder 20.

Subsequently, the controller 91 increases the outer tub valve opening degree of the flow rate adjuster 83b back to the opening degree V2 from 0 at the time t3 when the etching process is started, thus increasing the outer tub discharge flow rate of the second gas supply 80 back to the flow rate F8 from 0. As a result, the controller 91 is capable of increasing the concentration of the nitrogen dioxide, which is the intermediate that contributes to the oxidation reaction of the molybdenum film 101, on the surface of the wafer W during the etching process. This promotes the oxidation reaction of the molybdenum film 101, so that the etching rate of the molybdenum film 101 can be increased. That is, according to the substrate processing apparatus 1 of the third modification example, the controllability of the etching rate of the molybdenum film 101 can be improved.

Further, even after the time t3 when the etching process is started, the controller 91 maintains the inner tub discharge flow rate of the first gas supply 70 at 0. This allows the flow velocity of the processing liquid in the inner tub 11 to be reduced during the etching process, thus allowing the nitrogen dioxide to stay on the surface of the wafer W. As a result, as the oxidation reaction of the molybdenum film 101 is further accelerated, the etching rate of the molybdenum film 101 may be further increased.

Subsequently, the controller 91 performs the etching process in the period ranging from the time t3 to time t4.

Subsequently, the controller 91 performs the carrying-out process in the period ranging from the time t4 to time t5. In the carrying-out process, the controller 91 controls the non-illustrated elevating mechanism of the substrate holder 20 to raise the substrate holder 20, allowing the plurality of wafers W to be lifted from the processing liquid in the inner tub 11. The controller 91 lowers the outer tub valve opening degree of the flow rate adjuster 83b from the opening degree V2 to 0 in the period from the time t4 to the time t5, thus reducing the outer tub discharge flow rate of the second gas supply 80 from the flow rate F8 to 0.

In this way, in the substrate processing apparatus 1, in the period during which the plurality of wafers W are lifted from the processing liquid (the period from the time t4 to the time t5), the discharge of the oxygen gas from the first gas supply 70 and the second gas supply 80 is stopped. This leads to a decrease of the flow velocity of the processing liquid in the inner tub 11, and, as a result, it is possible to suppress the wafer W from falling off the substrate holder 20.

Subsequently, upon the completion of the carrying-out process at the time t5, the controller 91 increases the liquid feed pressure of the pump 55 from the pressure P2 to the pressure P0(>P2), thereby increasing the discharge flow rate of the processing liquid supplies 30_1 to 30_3 from the flow rate F6 to the flow rate F4(>F6). Furthermore, the controller 91 may control the flow rate adjuster 60 to close the bypass path 53. By increasing the discharge flow rate of the processing liquid supplies 30_1 to 30_3, the controller 91 is capable of returning the flow velocity of the processing liquid in the inner tub 11 to an initial flow velocity.

In the example shown in FIG. 11, by adjusting the discharge flow rate of the processing liquid supply 30, the inner tub discharge flow rate of the first gas supply 70, and the outer tub discharge flow rate of the second gas supply 80, the controller 91 adjusts the concentration of the nitrogen dioxide on the surface of the wafer W that contributes to the reaction of the molybdenum film 101. However, the present disclosure is not limited thereto, and the controller 91 may adjust the concentration of the nitrogen dioxide on the surface of the wafer W by adjusting at least one of the discharge flow rate of the processing liquid supply 30, the inner tub discharge flow rate of the first gas supply 70, and the outer tub discharge flow rate of the second gas supply 80. In this case, the controller 91 may increase the concentration of the nitrogen dioxide on the surface of the wafer W by performing at least one of a process of reducing the discharge flow rate of the processing liquid supply 30, a process of increasing the inner tub discharge flow rate of the first gas supply 70, and a process of increasing the outer tub discharge flow rate of the second gas supply 80.

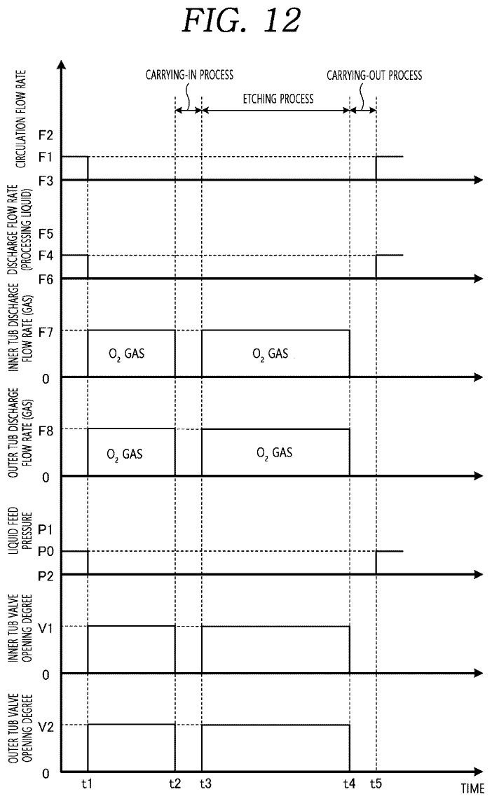

FIG. 12 is an explanatory diagram illustrating a concentration adjusting process according to a fourth modification example of the exemplary embodiment.

As shown in FIG. 12, the controller 91 increases the inner tub valve opening degree of the flow rate adjuster 73b from 0 to the opening degree V1 at the time t3 when the etching process is started, thereby increasing the inner tub discharge flow rate of the first gas supply 70 back to the flow rate F7 from 0. In this way, the controller 91 is capable of increasing the concentration of the nitrogen dioxide, which is the intermediate that contributes to the oxidation reaction of the molybdenum film 101, on the surface of the wafer W during the etching process. This accelerates the oxidation reaction of the molybdenum film 101, resulting in the increase of the etching rate of the molybdenum film 101. That is, in the substrate processing apparatus 1 according to the fourth modification example, the controllability of the etching rate of the molybdenum film 101 may be improved.

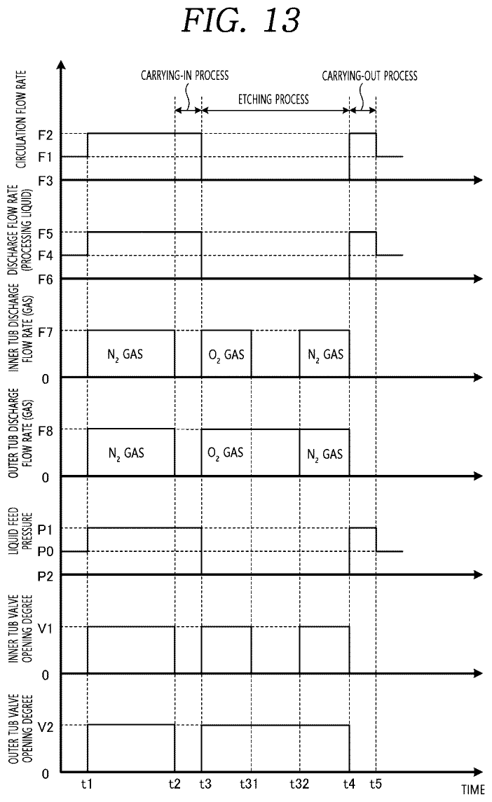

FIG. 13 is an explanatory diagram illustrating a concentration adjusting process according to a fifth modification example of the exemplary embodiment.

In the example shown in FIG. 13, the controller 91 reduces the concentration of the nitrogen dioxide on the surface of the wafer W before starting the carrying-in process and the carrying-out process for the wafer W, and increases the concentration of the nitrogen dioxide on the surface of the wafer W during the etching process.

Specifically, the controller 91 may increase the liquid feed pressure of the pump 55 from pressure P0 to pressure P1(>P0) at the time t1 before the time t2 when the carrying-in process is started, thus increasing the discharge flow rate of the processing liquid supplies 30_1 to 30_3 from flow rate F4 to flow rate F5(>F4). The pressure P0 and the flow rate F4 may be, for example, a liquid feed pressure of the pump 55 and a discharge flow rate of the processing liquid supplies 30_1 to 30_3 used in the previous substrate processing, respectively. Furthermore, the controller 91 may further increase the discharge flow rate of the processing liquid supplies 30_1 to 30_3 by controlling the opening/closing valve 59 to switch the filter bypass path 58 from a closed state to an open state. By increasing the discharge flow rate of the processing liquid supplies 30_1 to 30_3, the controller 91 is capable of increasing the flow velocity of the processing liquid in the inner tub 11.

Furthermore, the controller 91 increases the inner tub valve opening degree of the flow rate adjuster 73a from 0 to opening degree V1 at the time t1 to increase the inner tub discharge flow rate of the first gas supply 70 from 0 to the flow rate F7. By increasing the inner tub discharge flow rate of the first gas supply 70 to cause bubbling of the nitrogen gas in the inner tub 11, the controller 91 is capable of reducing the concentration of the oxygen (O₂) dissolved in the processing liquid in the inner tub 11.

In addition, the controller 91 increases the outer tub valve opening degree of the flow rate adjuster 83a from 0 to opening degree V2 at the time t1 to increase the outer tub discharge flow rate of the second gas supply 80 from 0 to flow rate F8. By increasing the outer tub discharge flow rate of the second gas supply 80 to cause bubbling of the nitrogen gas in the outer tub 12, the controller 91 is capable of reducing the concentration of the oxygen (O₂) dissolved in the processing liquid in the inner tub 11.

By performing these processes, the controller 91 may reduce the concentration of the nitrogen dioxide on the surface of the wafer W before starting the carrying-in process. Accordingly, the etching rate of the molybdenum film 101 is lowered before the carrying-in process is started. In the carrying-in process, since the lower end of each wafer W is first immersed in the processing liquid stored in the inner tub 11, an etching amount at the lower end of the wafer W tends to be greater than an etching amount at an upper end of the wafer W. As a resolution, the controller 91 may reduce a difference in the etching amount between the upper and lower ends of the wafer W by lowering the etching rate of the molybdenum film 101 before starting the carrying-in process and thus suppressing an increase of the etching amount at the lower end of the wafer W.

Subsequently, the controller 91 performs the carrying-in process in the period ranging from the time t2 to time t3. The controller 91 reduces the inner tub valve opening degree of the flow rate adjuster 73a to 0 from the opening degree V1 in the period from the time t2 to the time t3, thereby lowering the inner tub discharge flow rate of the first gas supply 70 to 0 from the flow rate F7. Further, the controller 91 reduces the outer tub valve opening degree of the flow rate adjuster 83a to 0 from the opening degree V2 in the period from the time t2 to the time t3, thereby lowering the outer tub discharge flow rate of the second gas supply 80 to 0 from the flow rate F8. As a result, the flow velocity of the liquid flow of the processing liquid in the inner tub 11 can be temporarily reduced, which makes it possible to suppress the wafer W from falling off the substrate holder 20.

Subsequently, the controller 91 performs the etching process in the period ranging from the time t3 to time t4.

The controller 91 reduces the liquid feed pressure of the pump 55 from pressure P1 to pressure P2(<P1) at the time t3 when the etching process is started, thereby reducing the discharge flow rate of the processing liquid supplies 30_1 to 30_3 from flow rate F5 to flow rate F6(<F5). By lowering the discharge flow rate of the processing liquid supplies 30_1 to 30_3, the controller 91 is capable of reducing the flow velocity of the liquid flow of the processing liquid in the inner tub 11.

The controller 91 increases the inner tub valve opening degree of the flow rate adjuster 73b from 0 to the opening degree V1 at the time t3 when the etching process is started, thus increasing the inner tub discharge flow rate of the first gas supply 70 from 0 to the flow rate F7. By increasing the inner tub discharge flow rate of the first gas supply 70 to cause bubbling of oxygen gas in the inner tub 11, the controller 91 is capable of increasing the concentration of the oxygen (O₂) dissolved in the processing liquid in the inner tub 11.

The controller 91 continues the bubbling of the oxygen gas in the inner tub 11 from the time t3 to time t31, and then lowers the inner tub valve opening degree of the flow rate adjuster 73b from the opening degree V1 to 0 at the time t31. As a result, the inner tub discharge flow rate of the first gas supply 70 is lowered to 0 from the flow rate F7. This leads to a decrease of the flow velocity of the liquid flow of the processing liquid in the inner tub 11 during the etching process, which allows the nitrogen dioxide to stay on the surface of the wafer W. As a result, as the oxidation reaction of the molybdenum film 101 is further promoted, the etching rate of the molybdenum film 101 can be further increased.

The controller 91 maintains the inner tub discharge flow rate of the first gas supply 70 at 0 from the time t31 to time t32, and then increases the inner tub valve opening degree of the flow rate adjuster 73a from 0 to the opening degree V1 at the time t32, thereby increasing the inner tub discharge flow rate of the first gas supply 70 from 0 to the flow rate F7. By increasing the inner tub discharge flow rate of the first gas supply 70 to cause bubbling of the nitrogen gas in the inner tub 11, the controller 91 is capable of reducing the concentration of the oxygen (O₂) dissolved in the processing liquid in the inner tub 11.

By performing these processes, the controller 91 may reduce the concentration of the nitrogen dioxide on the surface of the wafer W before starting the carrying-out process. Accordingly, the etching rate of the molybdenum film 101 is lowered before the carrying-out process is started. In the carrying-out process, since the lower end of the wafer W is last lifted from the processing liquid stored in the inner tub 11, an etching amount at the lower end of the wafer W tends to be greater than an etching amount at the upper end of the wafer W. As a resolution, the controller 91 may reduce a difference in the etching amount between the upper and lower ends of the wafer W by lowering the etching rate of the molybdenum film 101 before starting the carrying-out process and thus suppressing an increase of the etching amount at the lower end of the wafer W.

Furthermore, the controller 91 increases the outer tub valve opening degree of the flow rate adjuster 83b from 0 to the opening degree V2 at the time t3 to increase the outer layer discharge flow rate of the second gas supply 80 from 0 to the flow rate F8. By increasing the outer tub discharge flow rate of the second gas supply 80 to cause bubbling of the oxygen gas in the outer tub 12, the controller 91 is capable of increasing the concentration of the oxygen (O₂) dissolved in the processing liquid in the inner tub 11.

The controller 91 continues the bubbling of the oxygen gas in the outer tub 12 from the time t3 to a time t32, and then controls the flow rate controllers 83a and 83b to switch the gas discharged from the second gas supply 80 from the oxygen gas to a nitrogen gas at the time t32. In this way, by causing bubbling of the nitrogen gas in the outer tub 12, the controller 91 is capable of reducing the concentration of the oxygen (O₂) dissolved in the processing liquid in the inner tub 11.

Subsequently, the controller 91 performs the carrying-out process in the period ranging from time t4 to time t5. The controller 91 reduces the inner tub valve opening degree of the flow rate adjuster 73a to 0 from the opening degree V1 in the period from the time t4 to the time t5, thereby reducing the inner tub discharge flow rate of the first gas supply 70 to 0 from the flow rate F7. The controller 91 reduces the outer tub valve opening degree of the flow rate adjuster 83a to 0 from the opening degree V2 in the period from the time t4 to the time t5, thereby reducing the outer tub discharge flow rate of the second gas supply 80 to 0 from the flow rate F8. This leads to a decrease of the flow velocity of the liquid flow of the processing liquid in the inner tub 11, which makes it possible to suppress the wafer W from falling off the substrate holder 20.

Subsequently, upon the completion of the carrying-out process at the time t5, the controller 91 reduces the liquid feed pressure of the pump 55 from pressure P1 to pressure P0(<P1) to reduce the discharge flow rate of the processing liquid supplies 30_1 to 30_3 from flow rate F5 to flow rate F4(<F5). By lowering the discharge flow rate of the processing liquid supplies 30_1 to 30_3, the controller 91 is capable of returning the flow velocity of the liquid flow of the processing liquid in the inner tub 11 to an initial flow velocity.

### Other Modification Examples

Although the above exemplary embodiment has been described for the example of etching the molybdenum film 101 of the wafer W, the film to be etched may be a metal film other than the molybdenum film, such as a tungsten film.

In the above-described exemplary embodiment, the concentration adjusting process is started before the wafer W is carried in, and ended after the wafer W is carried out. However, the present disclosure is not limited thereto, and the timing for starting and ending the concentration adjusting process is not particularly limited.

As stated above, a substrate processing apparatus (for example, the substrate processing apparatus 1) according to the exemplary embodiment includes a processing tub (for example, the inner tub 11), a discharge opening group (for example, the plurality of discharge openings 32_1 to 32_2 provided in the processing liquid supplies 30_1 to 30_3), an overflow tub (for example, the outer tub 12), a circulation path (for example, the circulation path 50), a liquid feeder (for example, the pump 55), a first gas supply (for example, the first gas supply 70), a second gas supply (for example, the second gas supply 80), a first adjuster (for example, the flow rate controllers 73a and 73b), and a second adjuster (for example, the flow rate controllers 83a and 83b), and a controller (for example, the controller 91). In the processing tub, an etching process is performed by immersing a substrate (for example, the wafer W) having a metal film (for example, the molybdenum film 101) in a processing liquid. The discharge opening group is disposed below the substrate in the processing tub, and discharges the processing liquid to the inside of the processing tub. The overflow tub stores the processing liquid that has overflowed from the processing tub. The circulation path connects the overflow tub to the discharge opening group. The liquid feeder sends the processing liquid stored in the overflow tub to the circulation path. The first gas supply is disposed below the substrate in the processing tub, and discharges a gas to the inside of the processing tub. The second gas supply is disposed inside the overflow tub and discharges a gas to the inside of the overflow tub. The first adjuster adjusts a flow rate of the gas discharged from the first gas supply. The second adjuster adjusts a flow rate of the gas discharged from the second gas supply. The controller performs a concentration adjusting process of adjusting a concentration of an intermediate (for example, the nitrogen dioxide), which contributes to reaction of the metal film, on a surface of the substrate by controlling the liquid feeder, the first adjuster, and the second adjuster to adjust at least one of a flow rate of the processing liquid discharged from the discharge opening group, the flow rate of the gas discharged from the first gas supply, and the flow rate of the gas discharged from the second gas supply. Therefore, according to the substrate processing apparatus of the exemplary embodiment, controllability of the etching rate of the metal film can be improved.

Here, it should be noted that the above-described exemplary embodiments are illustrative in all aspects and are not anyway limiting. The above-described exemplary embodiments may be omitted, replaced and modified in various ways without departing from the scope and the spirit of claims.

### EXPLANATION OF CODES

1: Substrate processing apparatus
11: Inner tub
12: Outer tub
20: Substrate holder
30_1 to 30_3: Processing liquid supply
31_1 to 31_3: Nozzle
32_1 to 32_3: Discharge opening
50: Circulation path
51: Discharge path
52_1 to 52_3: Supply path
53: Bypass path
55: Pump
56: Heater
57: Filter
58: Filter bypass path
59: Opening/closing valve
60: Flow rate adjuster
70: First gas supply
71: Nozzle
72: Discharge opening
73a: Flow rate adjuster
73b: Flow rate adjuster
74a: Gas source
74b: Gas source
80: Second gas supply
81: Nozzle
82: Discharge opening
83a: Flow rate adjuster
83b: Flow rate adjuster
84a: Gas source
84b: Gas source
90: Control device
91: Controller
92: Storage
100: Polysilicon film
101: Molybdenum film
102: Silicon oxide film
W: Wafer

We claim:

1. A substrate processing apparatus, comprising:
a processing tub in which an etching process is performed by immersing a substrate having a metal film in a processing liquid;
a discharge opening group disposed below the substrate within the processing tub, and serving to discharge the processing liquid to an inside of the processing tub;
an overflow tub storing therein the processing liquid that has overflowed form the processing tub;
a circulation path connecting the overflow tub to the discharge opening group;
a liquid feeder configured to send the processing liquid stored in the overflow tub into the circulation path;
a first gas supply disposed below the substrate within the processing tub, and configured to discharge a gas to the inside of the processing tub;
a second gas supply disposed inside the overflow tub, and configured to discharge a gas to an inside of the overflow tub;
a first adjuster configured to adjust a flow rate of the gas discharged from the first gas supply;
a second adjuster configured to adjust a flow rate of the gas discharged from the second gas supply; and
a controller configured to perform a concentration adjusting process of adjusting a concentration of an intermediate, which contributes to a reaction of the metal film, on a surface of the substrate by controlling the liquid feeder, the first adjuster and the second adjuster to adjust at least one of a flow rate of the processing liquid discharged from the discharge opening group, the flow rate of the gas discharged from the first gas supply, or the flow rate of the gas supplied from the second gas supply.

2. The substrate processing apparatus of claim 1,
wherein the intermediate is a nitrogen dioxide (NO₂).

3. The substrate processing apparatus of claim 1,
wherein the first gas supply and the second gas supply discharge an inert gas or an oxygen-containing gas selectively as the gas.

4. The substrate processing apparatus of claim 3,
wherein the inert gas is a nitrogen (N₂) gas or a rare gas, and
the oxygen-containing gas is air, an oxygen (O₂) gas, or an ozone (O₃) gas.

5. The substrate processing apparatus of claim 3,
wherein the first gas supply and the second gas supply discharge the oxygen-containing gas as the gas, and
the controller increases, in the concentration adjusting process, a concentration of the intermediate on a surface of the metal film by performing at least one of a process of reducing the flow rate of the processing liquid discharged from the discharge opening group, a process of increasing the flow rate of the gas discharged from the first gas supply, and a process of increasing the flow rate of the gas discharged from the second gas supply.

6. The substrate processing apparatus of claim 5,
wherein the controller reduces a liquid feed pressure of the liquid feeder to reduce the flow rate of the processing liquid discharged from the discharge opening group.

7. The substrate processing apparatus of claim 5,
wherein the circulation path comprises:
a discharge path connected to the overflow tub;
a supply path branched from the discharge path and connected to the discharge opening group;
a bypass path branched from the discharge path and connected to the overflow tub; and
a third adjuster provided in the bypass path, and configured to adjust the flow rate of the processing liquid flowing through the bypass path, and
the controller controls the third adjuster to increase the flow rate of the processing liquid flowing through the bypass path, to thereby reduce the flow rate of the processing liquid discharged from the discharge opening group.

8. The substrate processing apparatus of claim 5,
wherein the controller stops a discharge of the gas from the first gas supply and a discharge of the second gas supply in a period during which the substrate is immersed in the processing liquid and in a period during which the substrate is lifted from the processing liquid.

9. The substrate processing apparatus of claim 3,
wherein the first gas supply and the second gas supply discharge the inert gas as the gas, and
the controller reduces, in the concentration adjusting process, a concentration of the intermediate on a surface of the metal film by performing at least one of a process of increasing the flow rate of the processing liquid discharged from the discharge opening group, a process of increasing the flow rate of the gas discharged from the first gas supply, or a process of increasing the flow rate of the gas discharged from the second gas supply.

10. The substrate processing apparatus of claim 9,
wherein the controller increases a liquid feed pressure of the liquid feeder to increase the flow rate of the processing liquid discharged from the discharge opening group.

11. The substrate processing apparatus of claim 9,
wherein the circulation path comprises:
a discharge path connected to the overflow tub;
a supply path branched from the discharge path and connected to the discharge opening group;
a filter provided in the discharge path;
a filter bypass path that bypasses the filter; and
an opening/closing valve configured to switch an open/closed state of the filter bypass path, and
the controller controls the opening/closing valve to switch the filter bypass path from a closed state into an open state, to thereby increase the flow rate of the processing liquid discharged from the discharge opening group.

12. The substrate processing apparatus of claim 9,
wherein the controller stops a discharge of the gas from the first gas supply and a discharge of the second gas supply in a period during which the substrate is immersed in the processing liquid and in a period during which the substrate is lifted from the processing liquid.

13. The substrate processing apparatus of claim 1,
wherein the metal film is a molybdenum film or a tungsten film.

14. The substrate processing apparatus of claim 1,
wherein the processing liquid contains at least nitric acid (HNO₃), phosphoric acid (H₃PO4) and water (H₂O) as components thereof.

15. A substrate processing method performed in a substrate processing apparatus,
wherein the substrate processing apparatus comprises:
a processing tub in which an etching process is performed by immersing a substrate having a metal film in a processing liquid;
a discharge opening group disposed below the substrate within the processing tub, and serving to discharge the processing liquid to an inside of the processing tub;
an overflow tub storing therein the processing liquid that has overflowed form the processing tub;
a circulation path connecting the overflow tub to the discharge opening group;
a liquid feeder configured to send the processing liquid stored in the overflow tub into the circulation path;
a first gas supply disposed below the substrate within the processing tub, and configured to discharge a gas to the inside of the processing tub;
a second gas supply disposed inside the overflow tub, and configured to discharge a gas to an inside of the overflow tub;
a first adjuster configured to adjust a flow rate of the gas discharged from the first gas supply; and
a second adjuster configured to adjust a flow rate of the gas discharged from the second gas supply, and
the substrate processing method comprises adjusting a concentration of an intermediate, which contributes to a reaction of the metal film, on a surface of the substrate by adjusting at least one of a flow rate of the processing liquid discharged from the discharge opening group, the flow rate of the gas discharged from the first gas supply, or the flow rate of the gas supplied from the second gas supply.
